(19) United States
(12) Patent Application Publication
(10) Pub. No.: US 2017/0271218 A1
(43) Pub. Date: Sep. 21, 2017

(54) CONTROL DEVICE, SUBSTRATE PROCESSING SYSTEM, SUBSTRATE PROCESSING METHOD, AND PROGRAM

(71) Applicant: Tokyo Electron Limited, Tokyo (JP)

(72) Inventors: Yuichi TAKENAGA, Iwate (JP); Takahito KASAI, Iwate (JP)

(21) Appl. No.: 15/459,553

(22) Filed: Mar. 15, 2017

(30) Foreign Application Priority Data
Mar. 17, 2016 (JP) 2016-053882

(51) Int. Cl. H01L 21/66; C23C 16/52; C23C 16/455; H01L 21/67

(52) U.S. Cl. CPC H01L 22/26; H01L 21/67069; H01L 21/67253; H01L 21/67288; C23C 16/52; C23C 16/455

(57) ABSTRACT

Provided is a control device for controlling an operation of a substrate processing apparatus that performs a predetermined processing on a substrate. The control device includes: a recipe storing unit that stores conditions of the predetermined processing including a first condition and a second condition different from the first condition; and a controller that determines, in a first processing performed on the substrate under the first condition and a second processing performed on the substrate under the second condition after the first processing, whether a result of the first processing or a result of the second processing is abnormal based on the result of the second processing and a result predicted from a relationship between the first condition and the second condition.

### CROSS-REFERENCE TO RELATED APPLICATIONS

This application is based on and claims priority from Japanese Patent Application No. 2016-053882 filed on Mar. 17, 2016 with the Japan Patent Office, the disclosure of which is incorporated herein in its entirety by reference.

### TECHNICAL FIELD

The present disclosure relates to a control device, a substrate processing system, a substrate processing method, and a program.

### BACKGROUND

In manufacturing a semiconductor device, when forming a film having desired characteristics on a substrate such as, for example, a semiconductor wafer (hereinafter, referred to as a “wafer”), an optimum film forming condition for obtaining the film having the desired characteristics is calculated in advance, and a film formation is performed on the substrate by using the film forming condition. Calculating the optimum film forming condition requires knowledge and experience related to semiconductor manufacturing apparatuses and semiconductor processes. Thus, the optimum film forming condition may not be easily calculated in some cases.

In the related art, as a system for calculating an optimum film forming condition, there is known a thermal processing system in which, when an operator merely inputs a target film thickness, a controller calculates an optimum temperature for approaching the target film thickness (see, e.g., Japanese Patent Laid-Open Publication No. 2013-207256).

### SUMMARY

According to an aspect, the present disclosure provides a control device for controlling an operation of a substrate processing apparatus that performs a predetermined processing on a substrate. The control device includes: a recipe storing unit that stores conditions of the predetermined processing including a first condition and a second condition different from the first condition; and a controller that determines, in a first processing performed on the substrate under the first condition and a second processing performed on the substrate under the second condition after the first processing, whether a result of the first processing or a result of the second processing is abnormal based on the result of the second processing and a result predicted from a relationship between the first condition and the second condition.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic diagram illustrating an exemplary substrate processing apparatus according to an exemplary embodiment of the present disclosure.

FIG. 2 is a schematic diagram illustrating an exemplary control device according to an exemplary embodiment of the present disclosure.

FIG. 3 is a diagram for explaining an influence of disturbance.

FIG. 4 is a diagram for explaining an influence of disturbance.

FIG. 5 is a diagram for explaining an influence of disturbance.

FIG. 6 is a flowchart illustrating an exemplary operation of the control device according to the exemplary embodiment.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

In the above-described system, even when the film formation processing is performed on the wafer using the optimum temperature calculated by the control unit, a film having desired characteristics may not be obtained due to an influence of disturbance.

Accordingly, in an aspect, the present disclosure is to provide a control device capable of detecting the influence of disturbance.

According to an aspect, the present disclosure provides a control device for controlling an operation of a substrate processing apparatus that performs a predetermined processing on a substrate. The control device includes: a recipe storing unit that stores conditions of the predetermined processing including a first condition and a second condition different from the first condition; and a controller that determines, in a first processing performed on the substrate under the first condition and a second processing performed on the substrate under the second condition after the first processing, whether a result of the first processing or a result of the second processing is abnormal based on the result of the second processing and a result predicted from a relationship between the first condition and the second condition.

In the above-described control device, the controller determines that the result of the first processing or the result of the second processing is abnormal when the result of the second processing tends to be opposite to the result predicted from the relationship between the first condition and the second condition, and determines that the result of the first processing and the result of the second processing are not abnormal when the result of the second processing does not tend to be opposite to the result predicted from the relationship between the first condition and the second condition.

In the above-described control device, the predetermined processing is performed on a plurality of substrates, and the controller determines whether the result of the first processing or the result of the second processing is abnormal, using at least one of the plurality of substrates.

In the above-described control device, when it is determined that the result of the first processing or the result of the second processing is abnormal, the controller notifies that the result is abnormal.

In the above-described control device, when it is determined that the result of the first processing or the result of the second processing is abnormal, the controller further notifies a cause presumed to be abnormal.

The above-described control device further includes a model storing unit that stores a process model representing an influence of a condition of the predetermined processing on a result of the predetermined processing. When it is determined that the result of the first processing or the result of the second processing is abnormal, the controller calculates a condition of the predetermined processing based on the process model stored in the model storing unit without using the result of the first processing and the result of the second processing, and when it is determined that the result of the first processing or the result of the second processing is not abnormal, the controller calculates a condition of the predetermined processing based on the result of the first processing, the result of the second processing, and the process model stored in the model storing unit.

In the above-described control device, the predetermined processing is a film formation processing, and the result of the predetermined processing is a film thickness of a film formed on the substrate.

In the above-described control device, the predetermined processing is an etching processing, and the result of the predetermined processing is an etching amount of a film forming material on the substrate.

According to another aspect, the present disclosure provides a substrate processing system including: a substrate processing apparatus that performs a predetermined processing on a substrate; and a control device that controls an operation of the substrate processing apparatus. The control device includes: a recipe storing unit that stores conditions of the predetermined processing including a first condition and a second condition different from the first condition; and a controller that determines, in a first processing performed on the substrate under the first condition and a second processing performed on the substrate under the second condition after the first processing, whether a result of the first processing or a result of the second processing is abnormal based on the result of the second processing and a result predicted from a relationship between the first condition and the second condition.

According to still another aspect, the present disclosure provides a substrate processing method including: performing a first processing on a substrate under a first condition; performing a second processing on the substrate under a second condition different from the first condition after the performing the first processing; and determining whether a result of the first processing or a result of the second processing is abnormal based on the result of the second processing and a result predicted from a relationship between the first condition and the second condition.

According to yet another aspect, the present disclosure provides a non-transitory computer-readable storage medium that stores a computer program which, when executed, causes a computer to perform the above-described substrate processing method.

According to the control device of the present disclosure, the influence of disturbance may be detected.

Hereinafter, an exemplary embodiment of the present disclosure will be described with reference to the drawings. In the present specification and drawings, components having substantially the same configurations will be denoted by the same symbols, and the overlapping descriptions thereof will be omitted.

(Substrate Processing Apparatus)

A substrate processing apparatus of the exemplary embodiment will be described. The substrate processing apparatus of the exemplary embodiment is an apparatus capable of accommodating a substrate holder in which a plurality of semiconductor wafers (hereinafter, referred to as “wafers”) as exemplary substrates are held at a predetermined interval in the vertical direction, and simultaneously performing a substrate processing on the plurality of wafers.

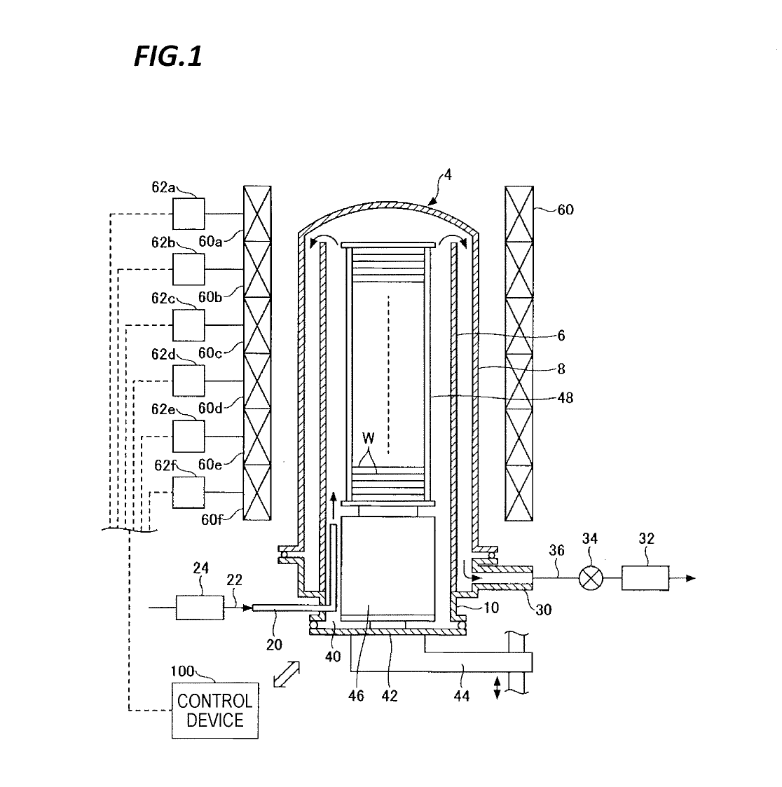

Hereinafter, descriptions will be made in reference to FIG. 1. FIG. 1 is a schematic diagram illustrating an exemplary substrate processing apparatus according to an exemplary embodiment of the present disclosure.

As illustrated in FIG. 1, the substrate processing apparatus includes a substantially cylindrical processing container 4 of which the longitudinal direction is a vertical direction. The processing container 4 has a dual pipe structure including an inner cylinder 6 of a cylindrical body and an outer cylinder 8 having a ceiling, which is arranged coaxially outside the inner cylinder 6. The inner cylinder 6 and the outer cylinder 8 are made of a heat-resistant material such as, for example, quartz.

The inner cylinder 6 and the outer cylinder 8 are held at the lower end portions thereof by a manifold 10 made of, for example, stainless steel. The manifold 10 is fixed to, for example, a base plate (not illustrated). Since the manifold 10 forms a substantially cylindrical internal space together with the inner cylinder 6 and the outer cylinder 8, it is assumed that the manifold 10 forms a part of the processing container 4. That is, the processing container 4 includes the inner cylinder 6 and the outer cylinder 8 made of a heat-resistant material (e.g., quartz), and a manifold 10 made of, for example, stainless steel. The manifold 10 is provided in the lower portion of the lateral surface of the processing container 4 to hold the inner cylinder 6 and the outer cylinder 8 from the lower side.

The manifold 10 is provided with a gas introduction portion 20 to introduce various kinds of gases, for example, a processing gas such as a film forming gas used for a film formation processing and an etching gas used for an etching processing, and a purge gas used for a purge processing, into the processing container 4. Although FIG. 1 illustrates a configuration in which one gas introduction portion 20 is provided, the present disclosure is not limited thereto. A plurality of gas introduction portions 20 may be provided depending on, for example, the kind of gas to be used.

The kind of the film forming gas is not particularly limited, but may be appropriately selected depending on the type of the film to be formed. For example, in a case of forming a polysilicon film on a wafer W, a gas containing monosilane (SiH₄), for example, may be used as the film forming gas.

The kind of the etching gas is not particularly limited, but may be appropriately selected depending on the type of the film forming material to be etched.

The kind of the purge gas is not particularly limited, but may be, for example, an inert gas (e.g., nitrogen (N₂) gas).

The gas introduction portion 20 is connected with a introduction pipe 22 to introduce various kinds of gases into the processing container 4. The introduction pipe 22 includes, for example, a flow rate adjusting unit 24 (e.g., a mass flow controller) for adjusting the gas flow rate or a valve (not illustrated) interposed therein.

Further, the manifold 10 is provided with a gas exhaust portion 30 to exhaust the atmosphere inside the processing container 4. The gas exhaust portion 30 is connected with a exhaust pipe 36 including a vacuum pump 32 and an opening variable valve 34, which are capable of controllably decompressing the inside of the processing container 4.

A furnace opening 40 is formed in the lower end portion of the manifold 10, and the furnace opening 40 is provided with a disk-like lid 42 made of, for example, stainless steel. The lid 42 is provided to be elevatable by, for example, an elevating mechanism 44 that functions as a boat elevator, and is configured to hermetically seal the furnace opening 40.

For example, a heat insulating cylinder 46 made of quartz is provided on the lid 42. For example, a wafer boat 48 made of quartz is placed on the heat insulating cylinder 46 to hold, for example, about 50 to 175 wafers W in a horizontal state at predetermined intervals in multi-tiers.

The wafer boat 48 is loaded (carried in) to the inside of the processing container 4 by moving up the lid 42 using the elevating mechanism 44, and various substrate processings are performed on the wafers W held in the wafer boat 48. After various substrate processings are performed, the wafer boat 48 is unloaded (carried out) from the inside of the processing container 4 to the lower loading region by moving down the lid 42 using the elevating mechanism 44.

For example, a cylindrical heater 60 capable of controllably heating the processing container 4 to a predetermined temperature is provided on the outer peripheral side of the processing container 4.

The heater 60 is divided into a plurality of zones, and heaters 60a to 60f are provided from the upper side to the lower side in the vertical direction. The heaters 60a to 60f are configured to independently control the heat generation amounts by power controllers 62a to 62f, respectively. Further, a temperature sensor (not illustrated) is provided on the inner wall of the inner cylinder 6 and/or the outer wall of the outer cylinder 8 in correspondence with the heaters 60a to 60f. Hereinafter, the zones provided with the heaters 60a to 60f are referred to as zones 1 to 6, respectively. Although FIG. 1 illustrates a configuration in which the heater 60 is divided into six (6) zones, the present disclosure is not limited thereto. For example, the heater 60 may be divided into five (5) or less zones, or seven (7) or more zones, from the upper side to the lower side in the vertical direction. Further, the heater 60 may not be divided into a plurality of zones.

The plurality of wafers W placed on the wafer boat 48 constitute one batch, and various substrate processings are performed by one batch. Further, at least one of the wafers W placed on the wafer boat 48 may be a monitor wafer. Further, the monitor wafer may be arranged corresponding to each of the divided heaters 60a to 60f.

Further, the substrate processing apparatus of the exemplary embodiment includes a control device 100 such as, for example, a computer to control the operation of the entire apparatus. The control device 100 is connected to a host computer by a wired or wireless communication means, and the substrate processing apparatus constitutes a substrate processing system.

(Control Device)

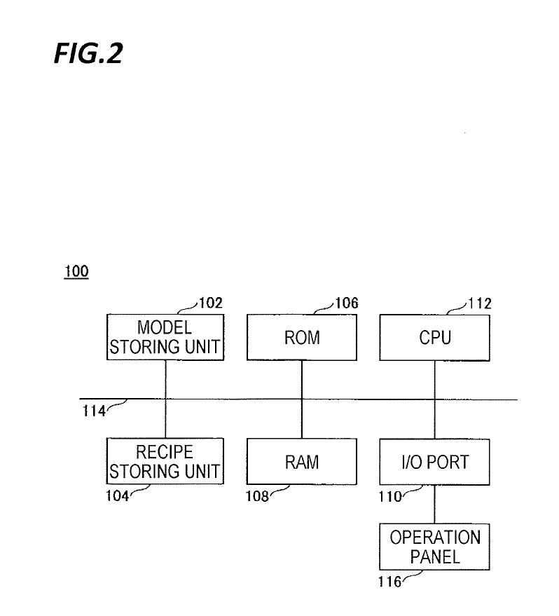

The control device 100 of the exemplary embodiment will be described with reference to FIG. 2. FIG. 2 is a schematic diagram illustrating an exemplary control device according to the exemplary embodiment.

As illustrated in FIG. 2, the control device 100 includes a model storing unit 102, an recipe storing unit 104, a read only memory (ROM) 106, a random access memory (RAM) 108, an I/O port 110, a central processing unit (CPU) 112, and a bus 114 that connects these components with each other.

The model storing unit 102 stores, for example, a process model and a thermal model.

The process model represents an influence of a substrate processing condition on a substrate processing result. Examples of the process model include a process model for a film formation processing that represents an influence of a film formation condition on a film formation result and a process model for an etching processing that represents an influence of an etching condition on an etching result.

Examples of the process model for a film formation processing include a temperature-film thickness model, a time-film thickness model, a pressure-film thickness model, and a gas flow rate-film thickness model. The temperature-film thickness model represents an influence of the temperature of the wafer W on the film thickness of the formed film. The time-film thickness model represents an influence of the film formation time on the film thickness of the formed film. The pressure-film thickness model represents an influence of the pressure in the processing container 4 on the film thickness of the formed film. The gas flow rate-film thickness model represents an influence of the flow rate of the film forming gas on the film thickness of the formed film.

Further, a process model for other film formation processings may be exemplified by a model representing an influence of film forming conditions such as, for example, the temperature of the wafer W, the film formation time, the pressure in the processing container 4, and the flow rate of the film forming gas on characteristics different from the film thickness of the formed film, for example, an impurity concentration, a sheet resistance, and a reflectance.

Examples of the process model for an etching processing include a temperature-etching amount model, a time-etching amount model, a pressure-etching amount model, and a gas flow rate-etching amount model. The temperature-etching amount model represents an influence of the temperature of the wafer W on the etching amount of the film forming material on the wafer W. The time-etching amount model represents an influence of the etching time on the etching amount of the film fainting material on the wafer W. The pressure-etching amount model represents an influence of the pressure in the processing container 4 on the etching amount of the film forming material on the wafer W. The gas flow rate-etching amount model represents an influence of the flow rate of the etching gas on the etching amount of the film forming material on the wafer W.

The model storing unit 102 may store some or all of the process models described above.

In addition to the process models described above, the model storing unit 102 stores a thermal model.

The thermal model is a model to be referred to when determining, for example, the set temperature of the heater 60 such that the temperature in the processing container 4 becomes a temperature calculated by the model representing the influence of the temperature of the wafer W on the substrate processing result, for example, the temperature-film thickness model or the temperature-etching amount model.

Further, in the models, since a non-optimal numerical value of the default is also considered depending on the substrate processing conditions or the state of the substrate processing apparatus, a learning function may be loaded by adding, for example, an expansion Kalman filter to software, so as to perform learning of the models.

The recipe storing unit 104 stores a process recipe that determines a control procedure depending on the kind of the substrate processings performed in the substrate processing apparatus. The process recipe is a recipe prepared for each substrate processing actually performed by an operator. The process recipe regulates substrate processing conditions including, for example, a temperature change, a pressure change, a timing of starting or stopping the supply of various gases, and a supply amount of various gases, from the carry-in of the wafer W into the substrate processing apparatus to the carry-out of the processed wafer W.

The ROM 106 is a storage medium that is constituted by, for example, an electrically erasable programmable read-only memory (EEPROM), a flash memory, or a hard disk, and stores an operation program of the CPU 112.

The RAM 108 functions as a work area of the CPU 112.

The I/O port 110 supplies a measurement signal for the substrate processing conditions such as, for example, a temperature, a pressure, and a gas flow rate to the CPU 112. Further, the I/O port 110 outputs the control signal output from the CPU 112 to respective units (including the power controller 62, the controller (not illustrated) of the opening variable valve 34, and the flow rate adjusting unit 24). Further, the I/O port 110 is connected with an operation panel 116 with which an operator operates the substrate processing apparatus.

The CPU 112 executes the operation program stored in the ROM 106, and according to the instructions from the operation panel 116, controls the operations of the substrate processing apparatus along the process recipe stored in the recipe storing unit 104.

Further, the CPU 112 calculates an optimum substrate processing condition based on the process model stored in the model storage unit 102. At this time, substrate processing conditions satisfying, for example, the in-plane uniformity of the wafer W or the inter-plane uniformity between the wafers W are calculated, based on, for example, a desired film characteristic or an etching amount stored in the read process recipe using the optimization algorithm such as, for example, the linear programming method or the quadratic programming method.

Further, the CPU 112 determines a set temperature of the heater 60 to be a temperature of the wafer W calculated by the process model, based on the thermal model stored in the model storing unit 102.

The bus 114 transmits information between the respective units.

Meanwhile, even when a substrate processing is performed using the optimum substrate processing conditions calculated based on the process model, the result of the substrate processing may tend to be opposite to a predicted result due to an influence of disturbance in some cases.

For example, even though the (N+1)th (N is an integer of 1 or more) film formation processing is performed under the same film formation conditions except that the film formation time is shorter than that of the Nth film formation processing, the film thickness may increase in some cases. Further, for example, even though the (N+1)th film formation processing is performed under the same film formation conditions except that the temperature of the wafer W is lower than that of the Nth film formation processing, the film thickness may increase in some cases.

Examples of disturbance, which may be considered herein, include an influence of the film thickness measuring device, an influence of maintenance of the substrate processing apparatus, an influence of an accumulated film thickness, an influence of the atmosphere of the loading area, an influence of the wafer W, and an influence of the number of wafers loaded.

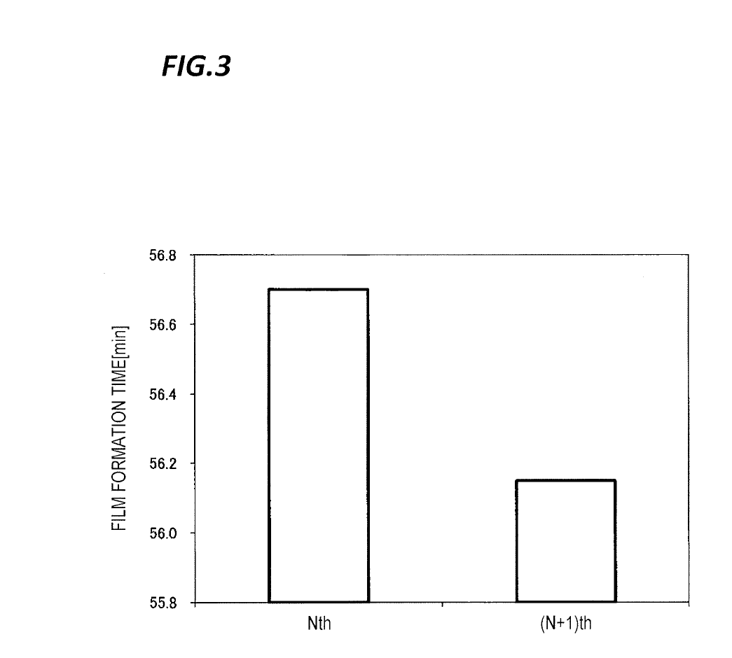

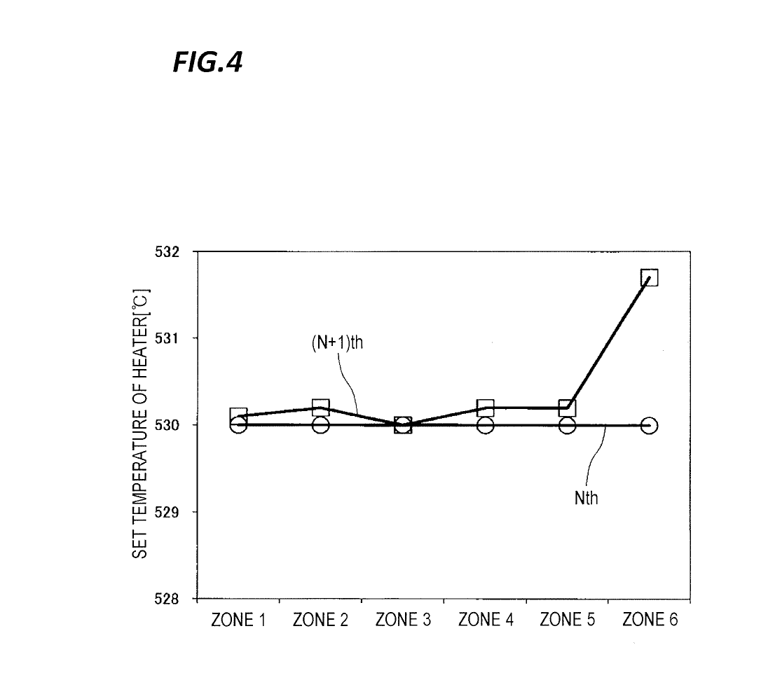

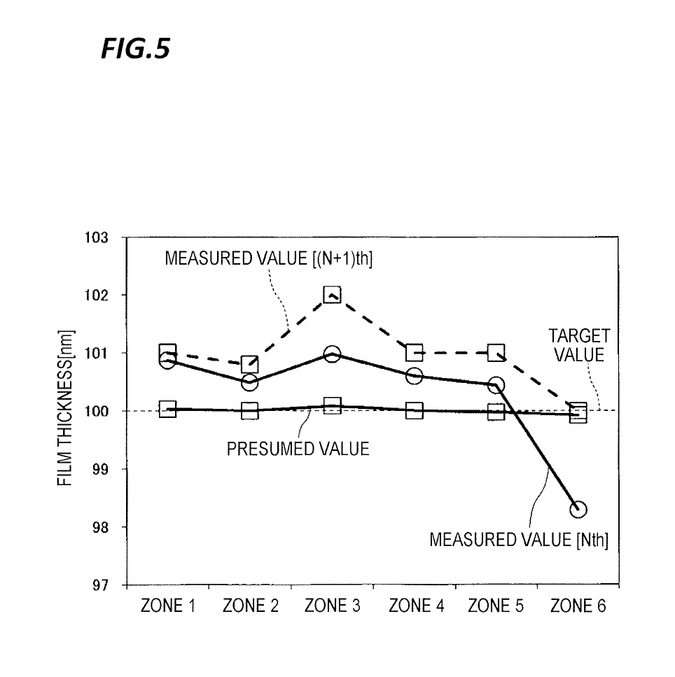

FIGS. 3 to 5 are diagrams for explaining the influence of disturbance, and illustrate an exemplary case where the film formation result tends to be opposite to a predicted film formation result due to the influence of disturbance. FIG. 3 illustrates a film formation time in the Nth and (N+1)th film formation processings. FIG. 4 illustrates a set temperature of the heater in each zone in the Nth and (N+1)th film formation processings. The horizontal axis represents a zone, and the vertical axis represents a set temperature (° C.) of the heater. FIG. 5 illustrates measured values of the film thickness of the film formed on the wafer W by the Nth and (N+1)th film formation processings and predicted values of the film thickness of the film formed on the wafer W by the (N+1)th film formation processing. In FIG. 5, the horizontal axis represents a zone, and the vertical axis represents a film thickness (nm).

As illustrated in FIG. 5, the measured value of the film thickness of the film obtained by the Nth film formation processing is larger than the target values in zones 1 to 5, and is smaller than the target film thickness in zone 6.

Therefore, the control device 100 changes the film formation time and the set temperature of the heater 60 such that the film thickness of the film formed on the wafer W in each zone becomes the target value, based on the measured value of the film thickness of the film formed on the wafer W by the Nth film formation processing, the target value, the process models (including the time-film thickness model and the temperature-film thickness model), and the thermal model. Further, the control device 100 sets the film formation condition after the film formation time and the set temperature of the heater 60 are changed, as a film formation condition for the (N+1)th film formation processing.

Specifically, the film formation time is shortened such that the film to be formed on the wafer W is thin as illustrated in FIG. 3, and the set temperature of the heater 60f in zone 6 is set to be higher than those in zones 1 to 5 such that the film to be formed on the wafer W in zone 6 is thick. In the exemplary embodiment, the time-film thickness model and the temperature-film thickness model are used as process models, but other process models may be used.

Referring back to FIG. 5, in zone 6, the measured value of the film thickness of the film obtained by the (N+1)th film formation processing is changed in a direction to become larger than the measured value of the film thickness of the film obtained by the Nth film formation processing. That is, the measured value of the film thickness of the film obtained by the (N+1)th film formation processing tends to be equal to a predicted result (in a direction approaching the predicted value).

Meanwhile, in zones 1 to 5, the measured values of the film thickness of the film obtained by the (N+1)th film formation processing is changed in a direction to become larger than the measured values of the film thickness of the film obtained by the Nth film formation processing. That is, the measured values of the film thickness of the film obtained by the (N+1)th film formation processing tends to be opposite to predicted results (in a direction away from the predicted values).

In this case, an optimum film formation condition in which the measured value of the film thickness of the obtained film becomes equal to the target value may not be obtained by calculating the (N+2)th optimum film formation condition based on the measured value of the film thickness of the film obtained by the (N+1)th film formation processing, the target value, the process model stored in the model storing unit 102, and the thermal model. Thus, the optimum film forming condition may not be calculated even when the film formation processing is required to be performed a plurality of times until the optimum film forming condition is calculated, or even when the film forming processing has been performed a plurality of times.

Accordingly, in the exemplary embodiment, the control device 100 determines, in a first processing performed on the substrate under the first condition and a second processing performed on the substrate under the second condition after the first processing, whether a result of the first processing or a result of the second processing is abnormal based on the result of the second processing and a result predicted from a relationship between the first condition and the second condition. Therefore, the influence of disturbance may be detected.

Next, descriptions will be made on an operation (adjustment processing) of the control device 100 capable of detecting the influence of the disturbance by taking a case where a polysilicon film is formed on the wafer W, as an example. The substrate processing is not limited to the film formation processing, but may be an etching processing.

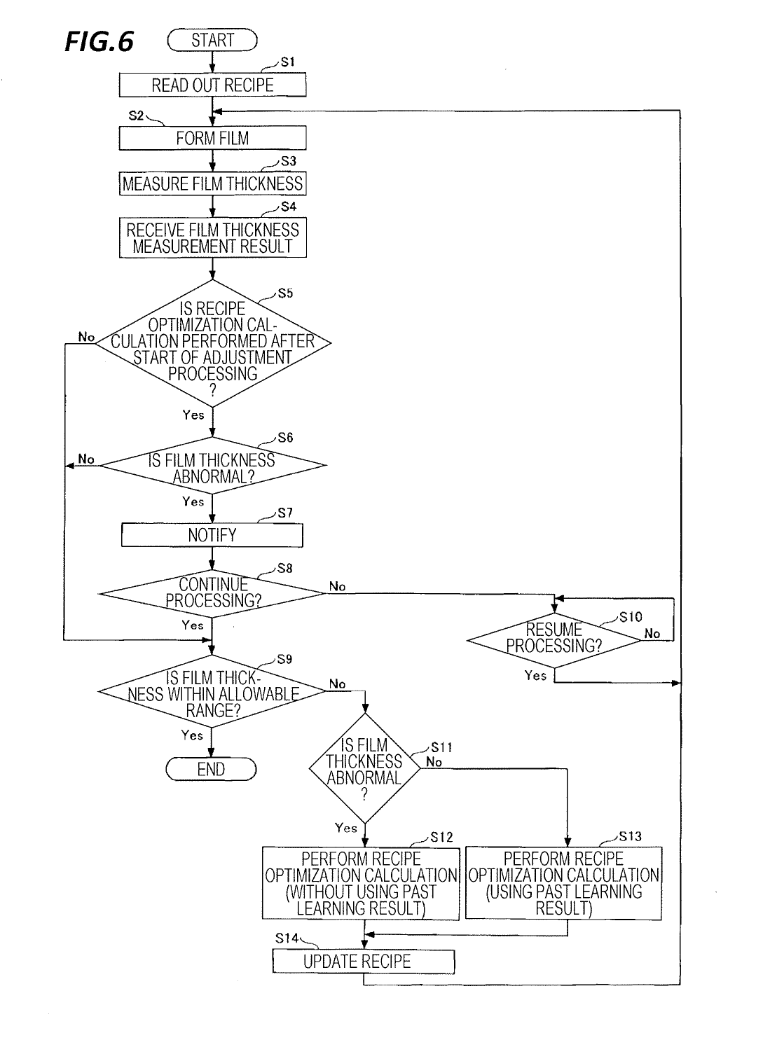

Hereinafter, descriptions will be made in reference to FIG. 6. FIG. 6 is a flowchart illustrating an exemplary operation of the control device according to the exemplary embodiment.

The adjustment processing of the exemplary embodiment may be formed at a set-up stage before the substrate processing is performed, or simultaneously with the substrate processing. Further, in the adjustment processing, the operator operates the operation panel 116 to select the kind of the process (e.g., film formation using SiH4 gas) and input a film thickness (target film thickness) of the polysilicon film to be formed for each zone.

When necessary information (e.g., the process type) is input, and a start instruction is received, the CPU 112 reads the process recipe corresponding to the input process type from the recipe storing unit 104 (step S1).

Next, a polysilicon film is formed on the wafer W (step S2). Specifically, the CPU 112 causes the lid 42 to be moved down so that the wafer boat 48 on which the wafer W is mounted at least in each zone is placed on the lid 42. Subsequently, the CPU 112 causes the lid 42 to be moved up so that the wafer boat 48 is carried into the processing container 4. Subsequently, the CPU 112 controls, for example, the flow rate adjusting unit 24, the opening variable valve 34, and the power controllers 62a to 62f according to the process recipe read from the recipe storing unit 104 to form a polysilicon film on the wafer W.

When the formation of the polysilicon film is completed, the CPU 112 causes the lid 42 to be moved down so that the wafer W on which the polysilicon film is formed is carried out. The host computer causes the carried-out wafer W to be conveyed to a measurement device such as, for example, a film thickness measuring device (not illustrated) to measure the film thickness of the polysilicon film (step S3). When the film thickness of the polysilicon film is measured, the film thickness measuring device transmits the measured film thickness to the CPU 112 via the host computer. Alternatively, the operator may operate the operation panel 116 to input the film thickness measured by the film thickness measuring device.

The CPU 112 receives the measured film thickness of the polysilicon film (step S4). Then, the CPU 112 determines whether or not the recipe optimization calculation has already been performed (step S5). The recipe optimization calculation will be described later.

When it is determined in step S5 that the recipe optimization calculation has already been performed, the CPU 112 determines whether or not the film thickness of the polysilicon film received in step S4 is abnormal (step S6). The determination whether or not the film thickness of the polysilicon film received in step S4 is abnormal is performed by determining whether or not the film thickness of the polysilicon film received in step S4 tends to be opposite to a predicted film thickness (hereinafter, referred to as a “predicted film thickness”).

Specifically, for example, in a case where the film thickness of the polysilicon film is increased even though the film formation processing is performed by shortening the film formation time without changing other film formation conditions (i.e., a case where the film thickness of the polysilicon film tends to be opposite to the predicted result), the CPU 112 determines that the film thickness is abnormal. Further, for example, in a case where the film thickness of the polysilicon film is increased even though the film formation processing is performed by reducing the temperature of the wafer W without changing other film formation conditions (i.e., a case where the film thickness of the polysilicon film tends to be opposite to the tendency of the predicted result), the CPU 112 determines that the film thickness is abnormal.

Upon the determination, when the film thickness of the polysilicon film tends to be opposite to the predicted film thickness in some of the wafers W, it may be determined that the film thickness is abnormal. In addition, when the film thickness of the polysilicon film tends to be opposite to the predicted film thickness in all the wafers, it may be determined that the film thickness is abnormal.

When it is determined in step S5 that the recipe optimization calculation has not been performed, the operation proceeds to step S9 without executing the film thickness abnormality determination (step S6).

When it is determined in step S6 that the film thickness of the polysilicon is abnormal, the CPU 12 notifies that the film formation result is abnormal (step S7). For example, the CPU 112 displays on the operation panel 116 that the film thickness is abnormal. Further, the CPU 112 may also notify a cause presumed to be abnormal (presumed cause). Specifically, for example, when the film thickness of the polysilicon film tends to be opposite to the predicted film thickness for all the wafers W, the CPU 112 notifies, for example, “the influence of the film thickness measuring device,” “the influence of the maintenance of the substrate processing apparatus,” “the influence of the accumulated film thickness,” and “the influence of the atmosphere in the loading area.” In addition, for example, when the film thickness of the polysilicon film tends to be opposite to the predicted film thickness for some of the wafers W, the CPU 112 notifies a presumed cause such as, for example, “an influence of the wafer W,” “an influence of the accumulated film thickness,” and “an influence of the number of wafers loaded.” Instead of the presumed cause, an error code correlated with each presumed cause may be notified.

When it is determined in step S6 that the film thickness of the polysilicon is not abnormal, the operation proceeds to step S9 without notifying that the film formation result is abnormal.

When it is notified that the film formation result is abnormal, the operator confirms the notified content, operates the operation panel 116, and selects whether to continue the processing or to stop the processing.

The CPU 112 determines whether or not an operation for continuing the processing has been performed within a predetermined time (step S 8).

When it is determined that the operation for continuing the processing has been performed within a predetermined time, the CPU 112 determines whether or not the film thickness of the polysilicon film falls within an allowable range of the target film thickness (step S9). The wording “within an allowable range” means that it is included within a predetermined allowable range from the input target film thickness, for example, within ±1% from the input target film thickness. When it is determined in step S8 that the operation for continuing the processing has not been performed within a predetermined time and the film formation processing is resumed by the operator (step S10), the CPU 112 returns the operation to step S2.

When it is determined that the film thickness of the polysilicon film falls within the allowable range of the target film thickness in step S9, the CPU 112 terminates the adjustment processing. When it is determined in step S9 that the film thickness of the polysilicon film does not fall within the allowable range of the target film thickness, the CPU 112 determines whether or not the film thickness of the polysilicon film received in step S4 is abnormal (step S11).

When it is determined in step S11 that the film thickness of the polysilicon film received in step S4 is abnormal, the CPU 112 executes the recipe optimization calculation without using the past learning result (step S12). In the recipe optimization calculation, a temperature of the wafer W and a film formation time in each zone, which are able to achieve the target film thickness, are calculated using the optimization algorithm, for example, from the process model stored in the model storing unit 102 without using the past learning result such as, for example, the processing result obtained after the adjustment processing is started. Further, the set temperatures of the heaters 60a to 60f are calculated so as to achieve the temperature of the wafer W calculated by the process model, based on the thermal model stored in the model storing unit 102.

When it is determined in step S11 that the film thickness of the polysilicon film received in step S4 is not abnormal, the CPU 112 executes the recipe optimization calculation by using the past learning result (step S13). In the recipe optimization calculation, a temperature of the wafer W and a film formation time in each zone, which are able to achieve the target film thickness, are calculated using the optimization algorithm, for example, from the process model stored in the model storing unit 102 while using the past learning result such as, for example, the processing result obtained after the adjustment processing is started. Further, the set temperatures of the heaters 60a to 60f are calculated so as to achieve the temperature of the wafer W calculated by the process model, based on the thermal model stored in the model storing unit 102.

Subsequently, the CPU 112 updates the set temperatures of the heaters 60a to 60f and the film formation time of the read process recipe with the set temperatures of the heaters 60a to 60f and the film formation time calculated in step S12 or step S13 (step S14), and returns the operation to S2. The process recipe may be updated by overwriting the existing process recipe. Alternatively, a new process recipe may be prepared separately from the existing process recipe.

When the adjustment processing is completed, the CPU 112 executes a film formation processing to form a polysilicon film on the wafer W. Specifically, the CPU 112 causes the lid 44 to be moved down by the elevating mechanism 44 so that the wafer boat 48 on which the wafer W is mounted is placed on the lid 42. Subsequently, the CPU 112 causes the lid 42 to be moved up by the elevating mechanism 44 so that the wafer boat 48 is carried into the processing container 4. Subsequently, the CPU 112 controls, for example, the flow rate adjusting unit 24, the opening variable valve 34, and the power controllers 62a to 62f according to the process recipe read from the recipe storing unit 104 to form a polysilicon film on the wafer W.

As described above, in the exemplary embodiment, the control device 100 determines, in a first processing performed on the substrate under the first condition and a second processing performed on the substrate under the second condition after the first processing, whether a result of the first processing or a result of the second processing is abnormal based on the result of the second processing and a result predicted from a relationship between the first condition and the second condition. Therefore, the influence of disturbance may be detected.

Further, in the exemplary embodiment, when it is determined that the result of the first processing or the result of the second processing is abnormal, the control device 100 notifies the abnormal result. Therefore, when there is an influence of disturbance, the operator may determine whether or not to continue the film formation processing after confirming the notified content. This makes it possible to suppress the film formation processing from being automatically continued despite the influence of disturbance. As a result, even though there is an influence of disturbance, the process control may be stably performed, thereby improving the process performance. In addition, since the operator needs to investigate the film formation result only when the control device 100 determines that the film formation result is abnormal, the burden on the operator may be reduced.

Further, in the exemplary embodiment, when it is determined that the result of the first processing or the result of the second processing is abnormal, the control device 100 notifies the cause presumed to be abnormal. Therefore, the adjustment processing may be easily performed even by an operator who has little knowledge or experience related to the substrate processing apparatus or the substrate processing process.

Further, in the exemplary embodiment, when it is determined that the result of the first processing or the result of the second processing is abnormal, the control device 100 calculates a predetermined processing condition based on the process model stored in the model storage unit 102 without using the results of the processings. Therefore, the predetermined processing conditions may be calculated without using the results of the processings affected by disturbance. Thus, it is possible to reduce the number of film formation processings required to calculate the optimum film forming condition.

The control device, the substrate processing apparatus, the substrate processing method, and the program have been described by means of the exemplary embodiment, but the present disclosure is not limited to the exemplary embodiments, and various changes and modifications may be made within the spirit of the present disclosure.

In the exemplary embodiment, descriptions have been made on an exemplary batch type apparatus in which one batch is constituted by a plurality of wafers W placed on a wafer boat 48, and film formation processing is performed in units of one batch, but the present disclosure is not limited thereto. For example, it may be a semi-batch type apparatus which collectively performs a film formation processing on a plurality of wafers W placed on a holder, or a single wafer type apparatus which performs a film formation processing one by one.

Further, in the exemplary embodiment, descriptions have been made on an exemplary case where the control apparatus 100 for controlling the operation of the substrate processing apparatus performs an adjustment processing, but the present disclosure is not limited thereto. For example, the adjustment processing may be performed by a control device (group controller) that collectively manages a plurality of apparatuses, or the host computer 500.

Further, in the exemplary embodiment, descriptions have been made on a mode of utilizing the abnormality determination of the film formation result for the recipe optimization calculation, but the present disclosure is not limited thereto. For example, the abnormality determination of the film formation result may be used for diagnosis of the health condition of the apparatus such as, for example, apparatus fault detection and classification (FDC) or statistical process control (SPC).

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A control device for controlling an operation of a substrate processing apparatus that performs a predetermined processing on a substrate, the control device comprising:
a recipe storing unit that stores conditions of the predetermined processing including a first condition and a second condition different from the first condition; and
a controller that determines, in a first processing performed on the substrate under the first condition and a second processing performed on the substrate under the second condition after the first processing, whether a result of the first processing or a result of the second processing is abnormal based on the result of the second processing and a result predicted from a relationship between the first condition and the second condition.

2. The control device of claim 1, wherein the controller determines that the result of the first processing or the result of the second processing is abnormal when the result of the second processing tends to be opposite to the result predicted from the relationship between the first condition and the second condition, and determines that the result of the first processing and the result of the second processing are not abnormal when the result of the second processing does not tends to be opposite to the result predicted from the relationship between the first condition and the second condition.

3. The control device of claim 1, wherein the predetermined processing is performed on a plurality of substrates, and
the controller determines whether the result of the first processing or the result of the second processing is abnormal, using at least one of the plurality of substrates.

4. The control device of claim 2, wherein when it is determined that the result of the first processing or the result of the second processing is abnormal, the controller notifies that the result is abnormal.

5. The control device of claim 4, wherein when it is determined that the result of the first processing or the result of the second processing is abnormal, the controller further notifies a cause presumed to be abnormal.

6. The control device of claim 1, further comprising:
a model storing unit that stores a process model representing an influence of a condition of the predetermined processing on a result of the predetermined processing,
wherein when it is determined that the result of the first processing or the result of the second processing is abnormal, the controller calculates a condition of the predetermined processing based on the process model stored in the model storing unit without using the result of the first processing and the result of the second processing, and
when it is determined that the result of the first processing or the result of the second processing is not abnormal, the controller calculates a condition of the predetermined processing based on the result of the first processing, the result of the second processing, and the process model stored in the model storing unit.

7. The control device of claim 1, wherein the predetermined processing is a film formation processing, and
the result of the predetermined processing is a film thickness of a film formed on the substrate.

8. The control device of claim 1, wherein the predetermined processing is an etching processing, and
the result of the predetermined processing is an etching amount of a film forming material on the substrate.

9. A substrate processing system comprising:
a substrate processing apparatus that performs a predetermined processing on a substrate; and
a control device that controls an operation of the substrate processing apparatus,
wherein the control device includes:
a recipe storing unit that stores conditions of the predetermined processing including a first condition and a second condition different from the first condition; and
a controller that determines, in a first processing performed on the substrate under the first condition and a second processing performed on the substrate under the second condition after the first processing, whether a result of the first processing or a result of the second processing is abnormal based on the result of the second processing and a result predicted from a relationship between the first condition and the second condition.

10. A substrate processing method comprising:
performing a first processing on a substrate under a first condition;
performing a second processing on the substrate under a second condition different from the first condition after the performing the first processing; and
determining whether a result of the first processing or a result of the second processing is abnormal based on the result of the second processing and a result predicted from a relationship between the first condition and the second condition.

11. A non-transitory computer-readable storage medium that stores a computer program which, when executed, causes a computer to perform the substrate processing method of claim 10.
